(19) United States
(12) Patent Application Publication
(10) Pub. No.: US 2026/0361300 A1
(43) Pub. Date: Nov. 12, 2026

(54) SEMICONDUCTOR DEVICE WITH TEMPERATURE DRIFT CANCELLATION AND ASSOCIATED DESIGN METHOD

(71) Applicant: CYNTEC CO., LTD., Hsinchu (TW)

(72) Inventors: Min-Rui Lai, Hsinchu (TW); Yu-Hsuan Pai, Hsinchu (TW)

(73) Assignee: CYNTEC CO., LTD., Hsinchu (TW)

(21) Appl. No.: 19/201,934

(22) Filed: May 8, 2025

(51) Int. Cl. H03K 17/14; H02M 3/156

(52) U.S. Cl. CPC H03K 17/145; H02M 3/156

(57) ABSTRACT

A semiconductor device includes a reference current generator circuit, a load circuit, and a processing circuit. The reference current generator circuit is configured to generate a first reference current with a first temperature coefficient. The load circuit has a first node configured to receive the first reference current and a second node configured to receive a reference voltage, wherein the load circuit has a resistance value with a second temperature coefficient, one of the first temperature coefficient and the second temperature coefficient is a positive temperature coefficient, and another of the first temperature coefficient and the second temperature coefficient is a negative temperature coefficient. The processing circuit is coupled to the first node of the load circuit, and is configured to generate a second reference current according to device characteristic of active devices, where the first reference current flows through one of the active devices.

### BACKGROUND OF THE DISCLOSURE

### 1. Field of the Disclosure

The present disclosure relates to a semiconductor device design, and more particularly, to a semiconductor device with temperature drift cancellation and an associated design method.

### 2. Description of the Prior Art

Semiconductor devices may be used in a variety of electronic devices. For example, some semiconductor devices may be designed to operate under reference currents provided from other semiconductor devices (e.g., current sources). However, a reference current output from a current source may vary due to certain factors such as variations in temperature. Thus, there is a need for an innovative current source design which is capable of generating a temperature-independent reference current.

### SUMMARY OF THE DISCLOSURE

One of the objectives of the present disclosure is to provide a semiconductor device with temperature drift cancellation and an associated design method.

According to a first aspect of the present disclosure, an exemplary semiconductor device is disclosed. The exemplary semiconductor device includes a reference current generator circuit, a load circuit, and a processing circuit. The reference current generator circuit is configured to generate a first reference current with a first temperature coefficient. The load circuit has a first node configured to receive the first reference current and a second node configured to receive a reference voltage, wherein the load circuit has a resistance value with a second temperature coefficient, one of the first temperature coefficient and the second temperature coefficient is a positive temperature coefficient, and another of the first temperature coefficient and the second temperature coefficient is a negative temperature coefficient. The processing circuit is coupled to the first node of the load circuit, and is configured to generate a second reference current according to device characteristic of active devices, wherein the first reference current flows through one of the active devices.

According to a second aspect of the present disclosure, an exemplary semiconductor device is disclosed. The exemplary semiconductor device includes a reference current generator circuit, a load circuit, and an operational-amplifier-less (OPAMP-less) processing circuit. The reference current generator circuit is configured to generate a first reference current with a first temperature coefficient. The load circuit has a first node configured to receive the first reference current and a second node configured to receive a reference voltage, wherein the load circuit has a resistance value with a second temperature coefficient, one of the first temperature coefficient and the second temperature coefficient is a positive temperature coefficient, and another of the first temperature coefficient and the second temperature coefficient is a negative temperature coefficient. The OPAMP-less processing circuit is coupled to the first node of the load circuit, and is configured to generate a second reference current according to a voltage at the first node of the load circuit.

According to a third aspect of the present disclosure, an exemplary method of designing a semiconductor device is disclosed. The exemplary method includes: determining a first reference current with a first temperature coefficient; defining that the first reference current is injected to a load circuit having a resistance value with a second temperature coefficient, wherein one of the first temperature coefficient and the second temperature coefficient is a positive temperature coefficient, and another of the first temperature coefficient and the second temperature coefficient is a negative temperature coefficient; generating a checking result by checking a temperature coefficient of a second reference current that is determined according to device characteristic of active devices, wherein the first reference current is defined to flow through one of the active devices; and adjusting configuration of the device characteristic of the active devices according to the checking result.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a first semiconductor device according to an embodiment of the present disclosure.

FIG. 2 is a diagram illustrating a second semiconductor device according to an embodiment of the present disclosure.

FIG. 3 is a diagram illustrating a reference current generator circuit according to an embodiment of the present disclosure.

FIG. 4 is a flowchart of a method of designing a semiconductor device according to an embodiment of the present disclosure.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

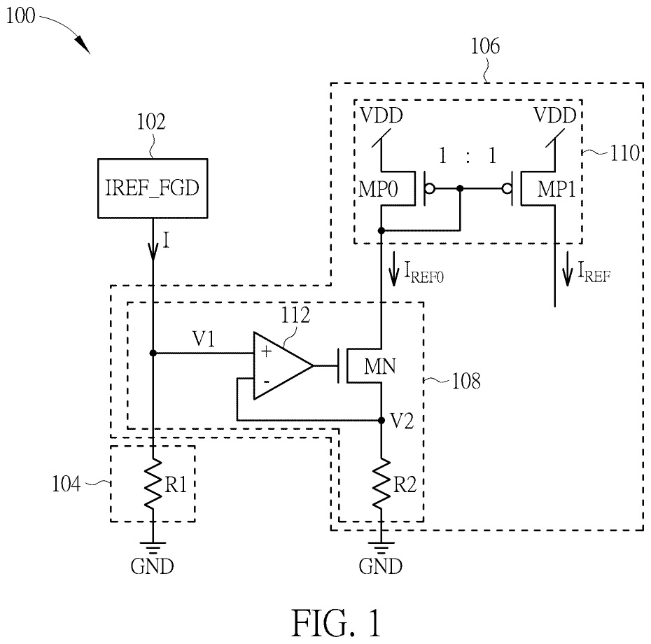

FIG. 1 is a diagram illustrating a first semiconductor device according to an embodiment of the present disclosure. The semiconductor device 100 may act as an operational amplifier (OPAMP) based current reference. As shown in FIG. 1, the semiconductor device 100 includes a reference current generator circuit (labeled by “IREF_FGD”) 102, a load circuit 104, and an OPAMP-based processing circuit 106. The reference current generator circuit 102 is configured to generate a reference current I. The load circuit 104 is coupled between the reference current generator circuit 102 and a reference voltage (e.g., ground voltage GND). The load circuit 104 may be implemented using a resistor R1 such as a high-resistance polysilicon resistor. The reference current I provided by the reference current generator circuit 102 and a resistance value of the resistor R1 have opposite temperature coefficients (TCs). For example, the reference current I may have a positive TC, and the resistor R1 may have a negative TC. Hence, with proper settings of the positive TC and the negative TC, a zero temperature coefficient (ZTC) voltage V1 can be generated at one end of the resistor R1 due to a proportional to absolute temperature (PTAT) current (i.e., I with a positive TC) passing through a complementary to absolute temperature (CTAT) resistor (i.e., R1 with a negative TC).

The OPAMP-based processing circuit 106 is configured to receive the ZTC voltage V1, and convert the ZTC voltage V1 into a ZTC reference current I_{REF} as an output current of the semiconductor device 100. As shown in FIG. 1, the OPAMP-based processing circuit 106 includes an OPAMP-based buffer 108 and a current mirror 110. The OPAMP-based buffer 108 includes an OPAMP 112, a metal-oxide-semiconductor (MOS) transistor MN (which is an N-type metal-oxide-semiconductor (NMOS) transistor), and a resistor (e.g., polysilicon resistor) R2. A non-inverting input terminal (labeled by “+”) of the OPAMP 112 receives the ZTC voltage V1, an output terminal of the OPAMP 112 is coupled to a control terminal (e.g., gate terminal) of the MOS transistor MN, and an inverting input terminal (labeled by “−”) is coupled to one connection terminal (e.g., source terminal) of the MOS transistor MN. Hence, the OPAMP-based buffer 108 forces the voltage V2 at the inverting input terminal (labeled by “−”) of the OPAMP 112 to be equal to the ZTC voltage V1 at the non-inverting input terminal (labeled by “+”) of the OPAMP 112. In this way, the voltage V2 is also a ZTC voltage.

When the resistor R2 is implemented using a low-TC resistor, the reference current I_{REF0} passing through the resistor R2 may be regarded as a ZTC current. The current mirror 110 is implemented using two MOS transistors MP1 and MP2 (which are P-type metal-oxide-semiconductor (PMOS) transistors), and is configured to generate the reference current I_{REF} through current mirroring of the reference current I_{REF0}. Since the reference current I_{REF0} is a ZTC current, the reference current I_{REF} output from the semiconductor device 100 is a ZTC current.

To achieve the reference current I_{REF} with a zero TC, the OPAMP-based buffer 108 needs the OPAMP 112 which occupies a large area and suffers various non-idealities, and needs the resistor R2 to be a low-TC resistor which also occupies a large area. To address these issues encountered by the semiconductor device 100, the present disclosure proposes another semiconductor device which is free of drawbacks of an OPAMP and a low-TC resistor.

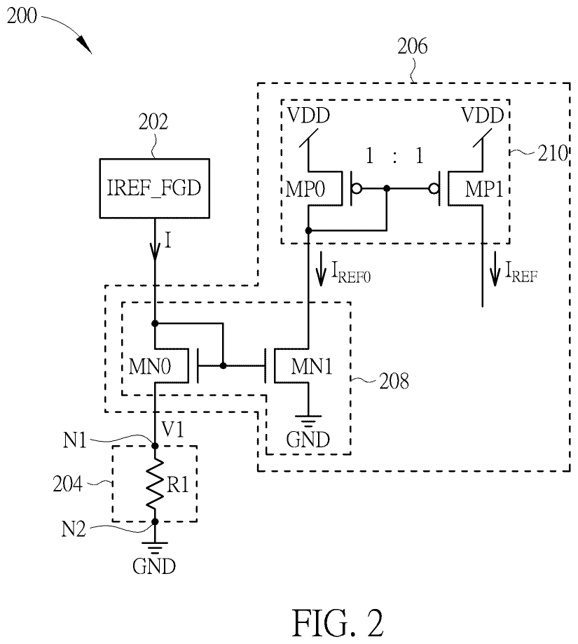

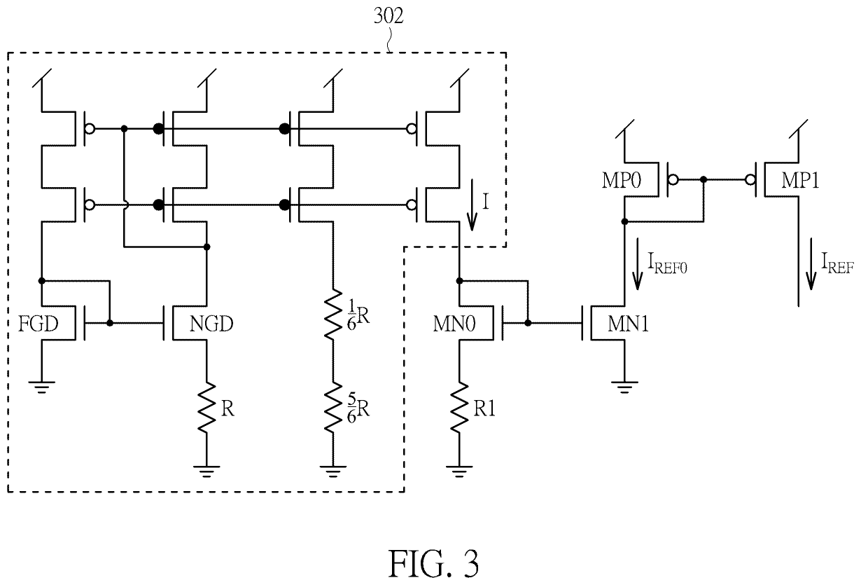

FIG. 2 is a diagram illustrating a second semiconductor device according to an embodiment of the present disclosure. The semiconductor device 200 may act as a device based current reference. As shown in FIG. 2, the semiconductor device 200 includes a reference current generator circuit (labeled by “IREF_FGD”) 202, a load circuit 204, and an OPAMP-less processing circuit 206. The reference current generator circuit 202 is configured to generate a reference current I. FIG. 3 is a diagram illustrating a reference current generator circuit according to an embodiment of the present disclosure. The reference current generator circuit 202 shown in FIG. 2 may be implemented using the reference current generator circuit 302 shown in FIG. 3. As shown in FIG. 3, a current value of the reference current I depends on a voltage difference (V_{gs_FGD}−V_{gs_NGD}) between gate-to-source voltages of NMOS transistors FGD and NGD and a resistance value of a resister R. However, this is for illustrative purposes only, and is not meant to be a limitation of the present disclosure. In practice, the present disclosure has no limitations on the circuit design of the reference current generator circuit.

The load circuit 204 has a first node N1 and a second node N2, where the first node N1 is configured to receive the reference current I supplied from the reference current generator circuit 202, and the second node N2 is configured to receive a reference voltage (e.g., ground voltage GND). In this embodiment, the load circuit 204 may be implemented using a resistor R1 such as a high-resistance polysilicon resistor. Hence, a first end of the resistor R1 acts as the first node N1, and a second end of the resistor R1 acts as the second node N2. When the reference current I flows through the resistor R1, it establishes a voltage V1 at the first node N1 of the load circuit 204. In this embodiment, the reference current I provided by the reference current generator circuit 102 and a resistance value of the resistor R1 have opposite TCs. For example, the reference current I may have a positive TC, and the resistor R1 may have a negative TC. Hence, with proper settings of the positive TC and the negative TC, the voltage V1 with a zero TC can be generated at the first node N1 of the load circuit 204 due to a PTAT current (i.e., I with a positive TC) passing through a CTAT resistor (i.e., R1 with a negative TC).

The OPAMP-less processing circuit 206 is coupled to the first node N1 of the load circuit 204, and is configured to generate a reference current I_{REF} according to the ZTC voltage V1. In this embodiment, the OPAMP-less processing circuit 206 includes an active-device circuit 208 and a current mirror 210, and is configured to generate the reference current I_{REF} according to device characteristic of active devices (particularly, device characteristic of active devices and follow-up current mirroring). The active-device circuit 208 includes two MOS transistors MN0 and MN1. By way of example, but not limitation, the device characteristic of active devices may be a size ratio between MOS transistors MN0 and MN1. The current mirror 210 includes two MOS transistors MP0 and MP1. In this embodiment, the MOS transistors MN0 and MN1 may be implemented using NMOS transistors, and the MOS transistors MP0 and MP1 may be implemented using PMOS transistors.

Regarding the active-device circuit 208, a first connection terminal (e.g., drain terminal) of the MOS transistor MN0 is coupled to the reference current generator circuit 202 and a control terminal (e.g., gate terminal) of the MOS transistor MN0, and a second connection terminal (e.g., source terminal) of the MOS transistor MN0 is coupled to the first node N1 of the load circuit 204; and a control terminal (e.g., gate terminal) of the MOS transistor MN1 is coupled to the control terminal (e.g., gate terminal) of the MOS transistor MN0, and a second connection terminal (e.g., source terminal) of the MOS transistor MN1 is configured to receive the reference voltage (e.g., ground voltage GND). Since the voltage V1 at the first node N1 is a ZTC voltage, a ZTC reference current I_{REF0} can be generated at a first connection terminal (e.g., drain terminal) of the MOS transistor MN1 through device characteristics of the MOS transistors MN0 and MN1. For example, the reference current I_{REF0} (I_{REF0}=I_{REF}) is determined by a plurality of factors, including the reference current I, the voltage V1, sizes of MOS transistors MN0 and MN1, etc. As mentioned above, the voltage V1 is a ZTC voltage. Hence, a size (i.e., aspect ratio) of the MOS transistor MN0 may be configured to be different from a size (i.e., aspect ratio) of the MOS transistor MN1, and a size ratio between the MOS transistors MN0 and MN1 can ensure that a temperature coefficient of the reference current I_{REF0} is small than a pre-defined threshold TH (e.g., TH=5%). Thus, under proper settings of sizes of MOS transistors MN0 and MN1 (particularly, size ratio between the MOS transistors MN0 and MN1), the reference current I_{REF0} (I_{REF0}=I_{REF}) may be regarded as a ZTC reference current.

Regarding the current mirror 210, a first connection terminal (e.g., drain terminal) of the MOS transistor MP0 is coupled to the first connection terminal (e.g., drain terminal) of the MOS transistor MN0 and a control terminal (e.g., gate terminal) of the MOS transistor MP0, and a second connection terminal (e.g., source terminal) of the MOS transistor MP0 is configured to receive another reference voltage (e.g., supply voltage VDD); and a control terminal (e.g., gate terminal) of the MOS transistor MP1 is coupled to the control terminal (e.g., gate terminal) of the MOS transistor MP0, a second connection terminal (e.g., source terminal) of the MOS transistor MP1 is configured to receive the another reference voltage (e.g., supply voltage VDD), and a first connection terminal (e.g., drain terminal) of the MOS transistor MP1 is configured to output the reference current I_{REF}. For example, a size (i.e., aspect ratio) of the MOS transistor MP0 is the same as a size (i.e., aspect ratio) of the MOS transistor MP1. Hence, the ZTC reference current I_{REF} can be generated and output by the semiconductor device 200 through current mirroring of the ZTC reference current I_{REF0} (I_{REF0}=I_{REF}).

Compared to the semiconductor device 100 using the OPAMP-based buffer 108 with large-sized OPAMP 112 and low-TC resistor R2 for generating the ZTC reference current I_{REF0}, the semiconductor device 200 using the active-device circuit 208 for generating the ZTC reference current I_{REF0} is free of drawbacks of the OPAMP 112 and low-TC resistor R2. For example, the active-device circuit 208 occupies a smaller area compared to the OPAMP-based buffer 108.

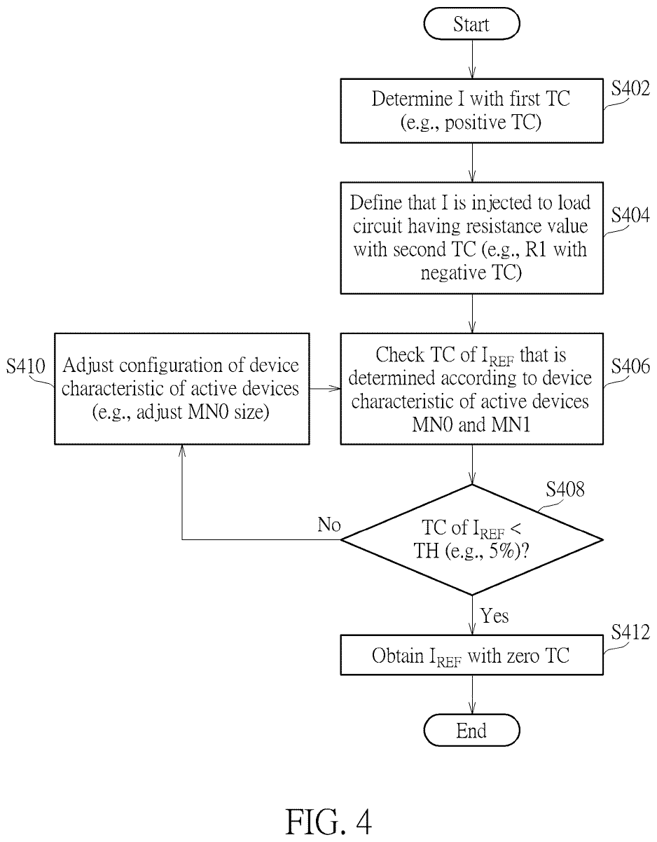

FIG. 4 is a flowchart of a method of designing a semiconductor device according to an embodiment of the present disclosure. The method may be employed to design the semiconductor device 200 shown in FIG. 2. Provided that the result is substantially the same, the steps are not required to be executed in the exact order shown in FIG. 4. In step S402, a first reference current with a first TC (e.g., reference current I with a positive TC) is determined. In step S404, the first reference current (e.g., reference current I) is defined to be injected to a load circuit having a resistance value with a second TC (e.g., resistor R1 with a negative TC). In step S406, a checking result is generated by checking a TC of a second reference current (e.g., reference current I_{REF}) that is determined according to device characteristic of active devices (e.g., a size ratio between MOS transistors MN0 and MN1), where the first reference current (e.g., reference current I) flows through one of the active devices (e.g., MOS transistor MN0). In step S408, it is checked to determine if the TC of the second reference current (e.g., reference current I_{REF}) is smaller than a pre-defined threshold TH (e.g., TH=5%). If the checking result indicates that the TC of the second reference current (e.g., reference current I_{REF}) is not smaller than the pre-defined threshold TH, it implies that the second reference current (e.g., reference current I_{REF}) is not a ZTC reference current. Hence, the flow proceeds to step S410 to change a size ratio between MOS transistors MN0 and MN1. For example, only one of the size (i.e., aspect ratio) of the MOS transistors MN0 and the size (i.e., aspect ratio) of the MOS transistors MN1 may be adjusted in step S410. For another example, both of the size (i.e., aspect ratio) of the MOS transistors MN0 and the size (i.e., aspect ratio) of the MOS transistors MN1 may be adjusted in step S410.

It should be noted that adjusting the configuration of the device characteristic of the active devices (e.g., adjusting one or both of MN0 size and MN1 size) is not stopped until the checking result indicates that the TC of the second reference current (e.g., reference current I_{REF}) is smaller than the pre-defined threshold. Hence, if the checking result indicates that the TC of the second reference current (e.g., reference current I_{REF}) is smaller than the pre-defined threshold (e.g., 5%), it implies that a ZTC reference current can be obtained under the current configuration of the device characteristic of the active devices (step S412).

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A semiconductor device comprising:
a reference current generator circuit, configured to generate a first reference current with a first temperature coefficient;
a load circuit, having a first node configured to receive the first reference current and a second node configured to receive a reference voltage,
wherein the load circuit has a resistance value with a second temperature coefficient, one of the first temperature coefficient and the second temperature coefficient is a positive temperature coefficient, and another of the first temperature coefficient and the second temperature coefficient is a negative temperature coefficient; and
a processing circuit, coupled to the first node of the load circuit, and configured to generate a second reference current according to device characteristic of active devices, wherein the first reference current flows through one of the active devices.

2. The semiconductor device of claim 1, wherein the first temperature coefficient is the positive temperature coefficient, and the second temperature coefficient is the negative temperature coefficient.

3. The semiconductor device of claim 1, wherein a voltage at the first node has a zero temperature coefficient.

4. The semiconductor device of claim 1, wherein the second reference current has a zero temperature coefficient.

5. The semiconductor device of claim 1, wherein the load circuit comprises:
a resistor, having a first end that acts as the first node of the load circuit and a second end that acts as the second node of the load circuit, wherein the first reference current flows through the resistor.

6. The semiconductor device of claim 1, wherein the processing circuit comprises:
a first metal-oxide-semiconductor (MOS) transistor, having a control terminal, a first connection terminal, and a second connection terminal, wherein the first connection terminal of the first MOS transistor is coupled to the reference current generator circuit and the control terminal of the first MOS transistor, and the second connection terminal of the first MOS transistor is coupled to the first node of the load circuit; and
a second MOS transistor, having a control terminal, a first connection terminal, and a second connection terminal, wherein the control terminal of the second MOS transistor is coupled to the control terminal of the first MOS transistor, and the second connection terminal of the second MOS transistor is configured to receive the reference voltage.

7. The semiconductor device of claim 6, wherein each of the first MOS transistor and the second MOS transistor is an N-type metal-oxide-semiconductor (NMOS) transistor.

8. The semiconductor device of claim 6, wherein the second reference current has a zero temperature coefficient.

9. The semiconductor device of claim 8, wherein a size of the first MOS transistor is different from a size of the second MOS transistor.

10. A semiconductor device comprising:
a reference current generator circuit, configured to generate a first reference current with a first temperature coefficient;
a load circuit, having a first node configured to receive the first reference current and a second node configured to receive a reference voltage,
wherein the load circuit has a resistance value with a second temperature coefficient, one of the first temperature coefficient and the second temperature coefficient is a positive temperature coefficient, and another of the first temperature coefficient and the second temperature coefficient is a negative temperature coefficient; and
an operational-amplifier-less (OPAMP-less) processing circuit, coupled to the first node of the load circuit, wherein the OPAMP-less processing circuit is configured to generate a second reference current according to a voltage at the first node of the load circuit.

11. The semiconductor device of claim 10, wherein the first temperature coefficient is the positive temperature coefficient, and the second temperature coefficient is the negative temperature coefficient.

12. The semiconductor device of claim 10, wherein the voltage at the first node has a zero temperature coefficient.

13. The semiconductor device of claim 10, wherein the second reference current has a zero temperature coefficient.

14. The semiconductor device of claim 10, wherein the load circuit comprises:
a resistor, having a first end that acts as the first node of the load circuit and a second end that acts as the second node of the load circuit, wherein the first reference current flows through the resistor.

15. The semiconductor device of claim 10, wherein the OPAMP-less processing circuit comprises:
a first metal-oxide-semiconductor (MOS) transistor, having a control terminal, a first connection terminal, and a second connection terminal, wherein the first connection terminal of the first MOS transistor is coupled to the reference current generator circuit and the control terminal of the first MOS transistor, and the second connection terminal of the first MOS transistor is coupled to the first node of the load circuit; and
a second MOS transistor, having a control terminal, a first connection terminal, and a second connection terminal, wherein the control terminal of the second MOS transistor is coupled to the control terminal of the first MOS transistor, and the second connection terminal of the second MOS transistor is configured to receive the reference voltage.

16. The semiconductor device of claim 15, wherein each of the first MOS transistor and the second MOS transistor is an N-type metal-oxide-semiconductor (NMOS) transistor.

17. The semiconductor device of claim 15, wherein the second reference current has a zero temperature coefficient.

18. The semiconductor device of claim 17, wherein a size of the first MOS transistor is different from a size of the second MOS transistor.

19. A method of designing a semiconductor device comprising:
determining a first reference current with a first temperature coefficient;
defining that the first reference current is injected to a load circuit having a resistance value with a second temperature coefficient, wherein one of the first temperature coefficient and the second temperature coefficient is a positive temperature coefficient, and another of the first temperature coefficient and the second temperature coefficient is a negative temperature coefficient;
generating a checking result by checking a temperature coefficient of a second reference current that is determined according to device characteristic of active devices, wherein the first reference current is defined to flow through one of the active devices; and
adjusting configuration of the device characteristic of the active devices according to the checking result.

20. The method of claim 19, wherein generating the checking result by checking the temperature coefficient of the second reference current that is determined according to the device characteristic of the active devices comprises:
checking if the temperature coefficient of the second reference current is smaller than a pre-defined threshold; and
adjusting the configuration of the device characteristic of the active devices according to the checking result comprises:
not stopping adjusting the configuration of the device characteristic of the active devices until the checking result indicates that the temperature coefficient of the second reference current is smaller than the pre-defined threshold.
